(19) United States
(12) Patent Application Publication
(10) Pub. No.: US 2003/0221717 A1
(43) Pub. Date: Dec. 4, 2003

(54) Composite thermal system

(75) Inventor: Steven Van Dessel, Troy, NY (US)

Correspondence Address: FOLEY AND LARDNER, SUITE 500, 3000 K STREET NW, WASHINGTON, DC, 20007, US

(73) Assignee: Rensselaer Polytechnic Institute

(21) Appl. No.: 10/448,086

(22) Filed: May 30, 2003

Related U.S. Application Data
(60) Provisional application No. 60/384,300, filed on May 30, 2002.

(51) Int. Cl. H01L 31/00; H01L 35/34

(52) U.S. Cl. 136/206; 136/248; 136/201

(57) ABSTRACT

There is provided a composite thermal system. The composite thermal system includes a thermoelectric system and a photovoltaic system. The photovoltaic system converts light energy into electrical energy. The thermoelectric system converts electrical energy into thermal energy. The photovoltaic system is integral with and electrically connected to the thermoelectric system for providing electrical energy to the thermoelectric system.

### RELATED INVENTIONS

This application claims priority to U.S. Provisional application serial No. 60/384,300, filed on May 30, 2002, entitled “Active Building Envelope Systems”, which is hereby incorporated by reference in its entirety.

### FIELD OF THE INVENTION

This invention is related generally to composite thermal systems incorporating both a thermoelectric system and a photovoltaic system.

### BACKGROUND OF THE INVENTION

Thermal systems for affecting the temperature of an object, such as a building, are known. For example, some thermal systems are designed to provide an ambient temperature within a building. Typically, such thermal systems for buildings include a thermal envelope, i.e., a structure that inhibits the passing of heat between the inside and outside of the building. Conventionally, thermal envelopes include insulated walls and/or roofs, for example.

Additionally, building thermal systems also typically include heating and/or cooling systems that compensate for the heat flow to or from the buildings. For example, heating and cooling systems such as air conditioning systems, furnaces, heat pumps, etc. are well known for this purpose. Thus, conventional strategies to mitigate thermal envelope losses or gains in buildings often rely on passive insulation approaches, and separate heating and cooling systems then compensate energy losses or gains that do occur.

Approaches to improve thermal systems for buildings include approaches directed to improving the thermal envelope. These approaches include double skin facades, walls with embedded evaporative cooling systems, dynamic insulation, integrated latent heat storage using phase-change materials, and development of multifunctional glazing materials. Efforts to develop enclosure systems with energy harvesting capabilities have also been made, for example, in the area of building integrated photovoltaic cells. Building integrated photovoltaic cells (BiPV) are photovoltaic systems that are fully integrated into the building's enclosure.

Approaches to improve thermal systems for buildings have also been directed to improving the heating or cooling system. For example, solar powered refrigeration has been studied, where power obtained from a photovoltaic system is used to drive a conventional heat-pump or ventilation system. In the solar powered refrigeration systems studied, solar energy is actively used (via its direct conversion to electricity) to extract heat for refrigeration purposes. In addition to conventional heat-pumps or ventilation units powered via photovoltaic systems, studies have also reported on the use of solid-state thermoelectric heat-pumps powered by photovoltaic cells. In these latter studies the solid-state thermoelectric heat-pumps are separated from the photovoltaic cells.

### SUMMARY OF THE INVENTION

In accordance with one aspect of the present invention, there is provided a composite thermal system. The composite thermal system comprises a thermoelectric system that converts electrical energy into thermal energy and a photovoltaic system that converts light energy into electrical energy. The photovoltaic system is integral with and electrically connected to the thermoelectric system for providing electrical energy to the thermoelectric system.

In accordance with another aspect of the present invention, the composite thermal system further comprises a substrate. The thermoelectric system comprises a thin film thermoelectric layer formed over the substrate, and the photovoltaic system comprises a thin film photovoltaic layer formed over the thin film thermoelectric layer.

In accordance with another aspect of the present invention, the composite thermoelectric system comprises a plurality of thermoelectric modules, and the composite thermal system further comprises a heat storage layer, the thermoelectric modules disposed adjacent to and thermally connected to the heat storage layer.

In accordance with another aspect of the present invention, the thermoelectric system comprises a plurality of thermoelectric modules. The photovoltaic system is disposed on a first side of the plurality of thermoelectric modules. The composite thermal system further comprises a thermal insulation layer disposed on a second side of the plurality of thermoelectric modules opposite to the first side, the thermal insulation layer having a plurality of ventilation pathways, each ventilation pathway extending from a respective thermoelectric module of the plurality of thermoelectric modules into the thermal insulation layer.

In accordance with another aspect of the present invention, the thermoelectric system comprises a thermoelectric layer and the photovoltaic system comprises a photovoltaic layer.

In accordance with another aspect of the present invention, there is provided a method of controlling the temperature of a structure. The structure comprises a thermoelectric system that converts electrical energy into thermal energy, a photovoltaic system that converts light energy into electrical energy, wherein the photovoltaic system is integral with and electrically connected to the thermoelectric system, for providing electrical energy to the thermoelectric system, and a plurality of thermoelectric regions. The method comprises controlling the electrical energy provided by the photovoltaic system to the thermoelectric system so that at least some of the thermoelectric regions have different temperatures.

In accordance with another aspect of the present invention, there is provided a method of controlling the temperature of a building. The building comprises a thermal envelope comprising a thermoelectric system that converts electrical energy into thermal energy, a photovoltaic system that converts light energy into electrical energy, wherein the photovoltaic system is integral with and electrically connected to the thermoelectric system for providing electrical energy to the thermoelectric system. The method comprises converting light energy to electrical energy via the photovoltaic system during the day and transferring the electrical energy to the thermoelectric system, converting the transferred electrical energy via the thermoelectric system to thermal energy to heat a heat storage layer of the thermal envelope, dissipating heat from the heat storage layer to the thermoelectric system towards air external to the building during the night, and using the dissipating heat to generate electricity via the thermoelectric system.

### BRIEF DESCRIPTION OF THE DRAWINGS

FIG. 1 is a schematic illustrating a composite thermal system according to an embodiment of the invention.

FIG. 2 is a cross-sectional view of a composite thermal system according to an embodiment of the invention.

FIG. 3 is an enlarged cross-sectional view of a portion of the composite thermal system of FIG. 2.

FIG. 4 is a cross-sectional view of a composite thermal system according to another embodiment of the invention.

FIG. 5 is an enlarged cross-sectional view of a portion of the composite thermal system of FIG. 4.

FIG. 6 is a cross-sectional view of a composite thermal system according to another embodiment of the invention.

FIG. 7 is a cross-sectional view of a composite thermal system according to another embodiment of the invention.

FIG. 8 is an enlarged cross-sectional view of a portion of the composite thermal system of FIG. 7.

FIG. 9 is a cross-sectional view of a composite thermal system according to another embodiment of the invention.

FIG. 10 is an enlarged cross-sectional view of a portion of the composite thermal system of FIG. 9.

FIG. 11 illustrates composite thermal system panels as a part of a building.

### DETAILED DESCRIPTION OF THE PREFERRED EMBODIMENTS

Reference will now be made in detail to embodiments of the present invention. Wherever possible, the same reference numbers will be used throughout the drawings to refer to the same or like parts.

The present inventor has realized that a number of advantages can be obtained for building thermal systems and other thermal systems by implementing a composite thermal system incorporating both a photovoltaic system and a thermoelectric system, where the photovoltaic system is integral with the thermoelectric system, i.e., the photovoltaic system is attached to the thermoelectric system. For example, in the case of such a composite thermal system in building thermal envelope applications, an integral system actively addresses the building heat dissipation problems at their source, i.e., the envelope.

In contrast to many conventional systems, according to aspects of the present invention, heat may be pumped in an opposite direction of the passive heat conduction direction in order to maintain a desired temperature gradient. For example, if a higher temperature is to be maintained within a building as compared to the surrounding air temperature, heat is pumped from the building envelope into the building, instead of simply losing heat through the building envelope.

In addition, because energy distribution storage and control technology may be embedded within the building envelope itself, significant reductions in building construction time due to system integration and shop manufacturing may be realized. When the PV system is integrated into the building enclosure system, these systems may also provide other building functions, such as providing protection against weather. In those applications where additional conventional heating and cooling equipment need not be included within the building system, equipment cost savings, and reduced building construction time can be realized.

Further in those applications where the photovoltaic and thermoelectric systems comprise solid state devices, reduced maintenance of the cooling and heating systems may be realized due to the reliability of solid state devices.

Because the heating and cooling functions can be distributed throughout the building envelope, localized control of the temperatures of the inner surfaces of the building envelope are possible, and thus such a system allows for optimization to respond to both local external conditions and internal comfort needs.

The composite system according to the present invention has applications in addition to building thermal envelopes. For example, when the system is implemented using thinner materials, such as thin film thermoelectric and photovoltaic materials, the composite thermal system has packaging and aerospace applications. Furthermore, implementations using thinner materials allows the composite thermal systems to be applied to existing buildings, to new construction, and to transparent materials such as glazing.

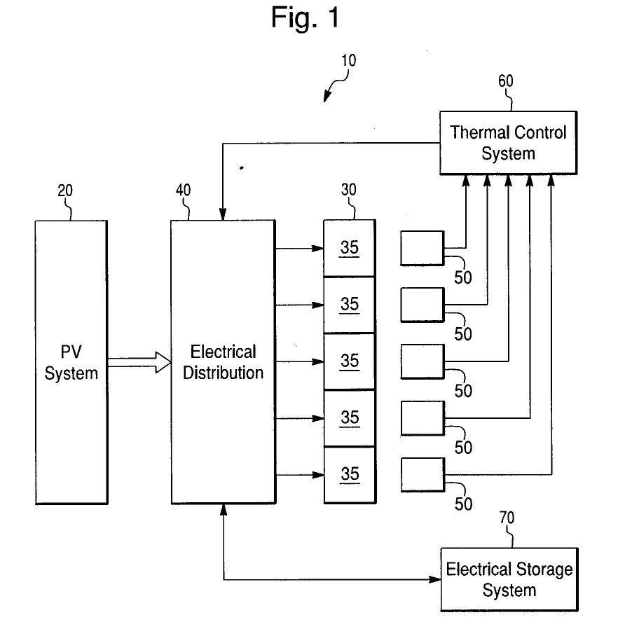

FIG. 1 is a schematic illustrating a composite thermal system 10 according to an embodiment of the invention. The composite thermal system 10 includes a photovoltaic system 20 and a thermoelectric system 30. Photovoltaic systems are systems using photovoltaic devices that convert electromagnetic radiation directly into electricity. The photovoltaic system 20 converts light energy into electrical energy. The photovoltaic system 20 is integral with and electrically connected to the thermoelectric system 30, and thus can supply electrical energy to the thermoelectric system 30. In turn, the thermoelectric system 30 converts electrical energy into thermal energy. Thus, the thermoelectric system 30 provides heating or cooling by converting electrical energy into thermal energy. In general, thermoelectric systems are heat engines in which charge carriers serve as the working fluid. The thermoelectric system 30 can be converted from heating to cooling by reversing the polarity of the current supplied thereto.

The photovoltaic system 20 supplies electrical energy to the thermoelectric system 30 via an electrical distribution system 40. The electrical distribution system 40 includes the circuitry as necessary to distribute the electrical energy from the photovoltaic system 20 to different thermoelectric regions 35 of the thermoelectric system 30. The electrical distribution system can consist of conventional wiring, integrated circuits, or adaptive solid state circuitry, for example. The thermal system 10 may also include an electrical storage system 70. In this case electrical energy produced by the photovoltaic system 20, which is not distributed to the thermoelectric regions 35 may be diverted to the electrical storage system 70. In this regard the electrical storage system 70 may be a battery as is known in the art for storing electrical energy. The electrical storage system 70 may be integrated with the remaining structures of the system 10, or may be separate therefrom.

When the photovoltaic system 20 is not producing enough electrical energy to supply the thermoelectric regions 35, such as at night, during a cloudy day, or when the temperature gradient to be maintained is large, the electrical energy stored in the electrical storage system 70 may be diverted to the thermoelectric regions 35.

The thermal system 10 may also include temperature sensors 50 and a thermal control system 60 to provide thermal feedback and temperature control. For thermal systems where temperature control of the individual thermoelectric regions 35 is desired, the thermal sensors 50 are individually associated with a respective thermoelectric region 35. For example, individual thermal sensors may be disposed near or at respective of the thermoelectric regions 35 to measure the temperature near or at that respective thermoelectric region. Alternatively, the thermoelectric regions 35 can also serve as the thermal sensors themselves. In the latter case, no separate temperature sensors 50 are needed.

The thermal control system 60 receives signals indicative of the temperatures detected by the thermal sensors 50, and based on these signals, and desired temperature setting of the thermoelectric regions 35, controls the electrical distribution system 40 to provide an appropriate amount of electrical energy in the form of current and voltage to the thermoelectric regions 35. In this regard, the thermal control system 60 may include an interface with control software, allowing for smart control.

The thermoelectric regions 35 may have different individual temperature settings, and thus these regions 35 may be controlled to have different temperatures as desired. Thus, the present system 10 can provide flexibility in providing different temperatures for the different thermoelectric regions 35 as desired. Because the heating and heat dissipation are localized, the temperature may be controlled to vary over a relatively short distance.

As an alternative to providing different temperature control for each of the thermoelectric regions 35, the thermoelectric regions 35 may be controlled to provide the same temperature. The temperature control in this case may be simplified, and a single thermal sensor 50 may be used. Also in this case the control may be simplified by controlling the different thermoelectric regions to be provided with the same electrical energy.

The thermal sensors 50 may be any conventional thermal sensors such as a thermocouple, for example. Alternatively, the thermoelectric regions 35 can also serve as the thermal sensors themselves.

The thermoelectric regions 35 may each comprise one or more thermoelectric devices, such as thermoelectric modules for example. The present invention is not limited to any particular type of thermoelectric device, and suitable thermoelectric devices may comprise thermoelectric materials such as filled skutterdites, chlathrate structured compounds, fine grain sized thermoelectric materials, and film shaped thermoelectric materials, for example. The thermoelectric devices may comprise single stage devices, or multistage cascade structures, for example. The thermoelectric devices may also comprise thin-film thermoelectric materials, or may be thermoelectric devices comprising organic thermoelectric materials.

The photovoltaic system 20 may comprise one or more photovoltaic devices. The present invention is not limited to any particular type of photovoltaic device, and suitable photovoltaic devices may comprise materials such as conventional crystalline silicon, thin film silicon, amorphous silicon, gallium arsenide and other semiconductor materials. Suitable photovoltaic devices also include single junction or multi-junction solar cells, and dye-doped solar cells based on titanium dioxide. Suitable photovoltaic devices also include photovoltaic materials such as ceramic-based semiconductors, polymeric or polymeric hybrid materials. The photovoltaic devices may also include optics such as concentrator lenses and mirrors, antireflective coatings, textured cell surfaces and back reflectors.

In addition to a photovoltaic system and a thermoelectric system, the following embodiments may include an electrical distribution system, thermoelectric regions, temperature sensors, thermal control system and electrical storage system.

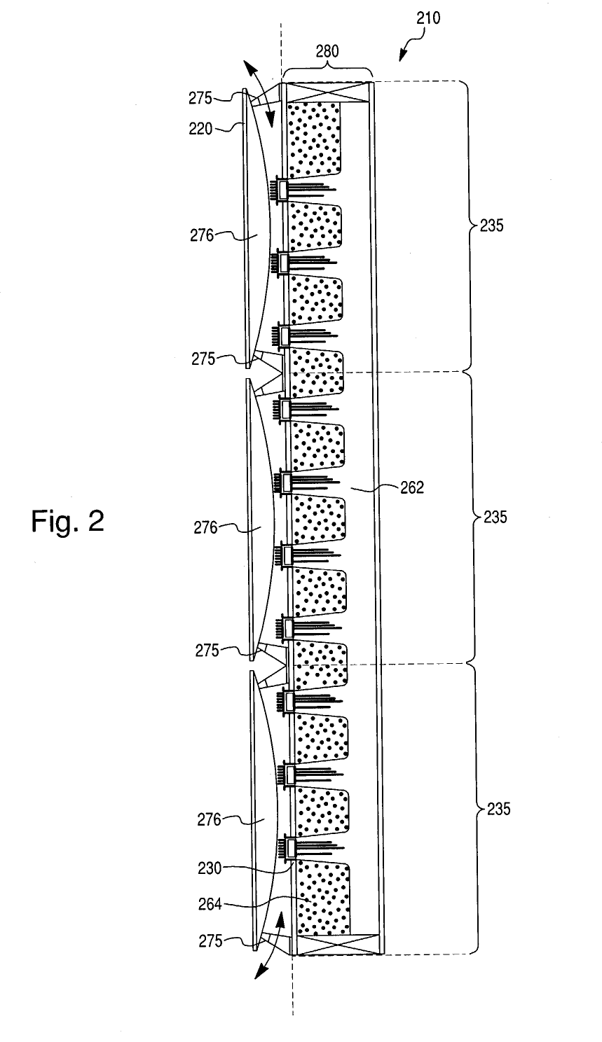

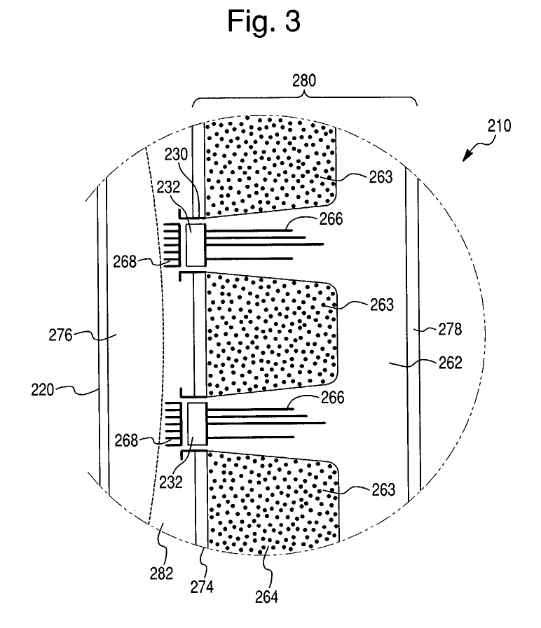

FIGS. 2 and 3 are cross-sectional views of a composite thermal system 210 according to an embodiment of the present invention. FIG. 3 is an enlarged view of a portion of the composite thermal system illustrated in FIG. 2. The composite thermal system 210 of FIGS. 2 and 3 is an active building envelope system where the photovoltaic system 220 and the thermoelectric system 230 are part of a building thermal envelope. The composite thermal system 210 also includes a heat storage layer 262, a thermal insulating layer 264, first heat sinks 266, second heat sinks 268, first supporting structure 274, second supporting structure 276 and third supporting structure 278.

The first 274 and third 278 supporting structures support the thermoelectric system 210, heat storage layer 262, and thermal insulating layer 264. The first 274 and third 278 supporting structures may comprise the external skin of a structural load bearing panel 280, for example. In this case, in addition to the first 274 and third 278 supporting structures, the heat storage layer 262, thermal insulating layer 264, first heat sinks 266, and second heat sinks 268 are all integrated into the load bearing panel 280. The load bearing panel 280 as a whole, including insulating layer 264 and heat storage layer 262, may provides structural support as a building panel. The panel 280 in application may be a part of the building thermal envelope of a building. The first 274 and third 278 supporting structures may comprise plywood or some other building materials such as metals or fiber reinforced polymer composite, for example.

The second supporting structure 276 may comprise a metallic or fiber reinforced polymer composite material, or any other material suitable for supporting photovoltaic materials. The second supporting structure 276 acts to support the photovoltaic system 220. The second supporting structure 276 is attached to the first supporting structure 274, and thus the structures are integral. In this regard, the first supporting structure 274 may include a number of supporting brackets 275 that extend outwardly from the first supporting structure 274. These supporting brackets 275 can be made from a metal or any other suitable material. The second supporting structure 276 may be hung and secured on the supporting brackets 275 to attach the second supporting structure 276 to the first supporting structure 274.

The thermoelectric system 230 includes a plurality of thermoelectric modules 232. The present invention is not limited to the particular thermoelectric module, and the thermoelectric modules may comprise any thermoelectric module or thermoelectric system, as disclosed above with respect to FIG. 1. The thermoelectric modules 232 may be grouped as desired, and may be arranged to correspond to thermoelectric regions 235 as also disclosed above with respect to FIG. 1. Each thermoelectric region 235 may be associated with one or more of the thermoelectric modules 232.

The grouping of the thermoelectric modules 232 according to thermoelectric regions 235 allows for a particular region to be heated or cooled as desired, and provides for much flexibility in differential heating/cooling of the different regions 235. For example, if the composite thermal system 210 is to be used as part of a building thermal envelope for a building having several rooms, the regions 235 may be grouped according to the different rooms of the building, and the different rooms heated or cooled to have different temperatures.

The composite thermal system 210 of FIGS. 2 and 3 may be particularly suited for a building thermal envelope in a heating dominated climate. In this regard the composite thermal system 210 includes the heat storage layer 262. The heat storage layer 262 comprises a material with a high heat storage capacity. The heat storage layer 262 may comprise a phase change material, for example, where heat supplied to the phase change material is stored as the latent heat of phase transformation of the material. Suitable phase change materials may include salt hydrates, paraffins, or fatty acids. Alternatively, these phase change materials can also be incorporated into conventional building materials such as concrete or drywall, for example by means of micro-encapsulation. In the latter case, the heat storage layer 262 may also provide structural support for the thermoelectric layer 30, and act as a load bearing structure for the building, for example to support a roof load. Heat generated by the thermoelectric modules 232 is transferred to the heat storage material of the heat storage layer 262, or vice versa if the modules 232 are in cooling mode.

Heat is transferred between the thermoelectric modules 232 and the heat storage layer 262 via thermal conduction paths between thermal insulation regions 263 of the thermal insulating layer 264. The thermal conduction paths may be extensions of the heat storage layer 262 through the thermal insulating layer 264 towards respective thermoelectric modules 232. In this regard, the thermal insulation regions 263 are disposed adjacent the heat storage layer 262 and laterally adjacent the plurality of thermoelectric modules 232. Alternatively, the thermal conduction paths may comprise a material with good heat conduction properties extending from the heat storage layer 262 through the thermal insulating layer 264 towards respective thermoelectric modules 232. Appropriate materials with good heat conduction properties include metals such as copper or aluminum, for example.

The thermal conduction paths from respective thermoelectric modules 232 to the heat storage layer 262 may also include first heat sinks 266. Each heat sink of the first heat sinks 266 is disposed adjacent to a respective of the thermoelectric modules 232 in the thermal conduction path, and thus acts to provide a thermal conduction path between its respective thermoelectric module 232 and the heat storage layer 262. In this regard, it is preferred that the first heat sinks 266 have good thermal conduction properties, and may be made of a material with good heat conduction properties such as a metal, such as copper or aluminum, for example. The heat sinks 266 should be in good thermal contact with the thermoelectric modules 232, for example by applying an adhesive with good thermal conductivity. The first heat sinks 266 should also be of a shape such that heat is dissipated between the first heat sinks 266 and the heat storage layer 262. For example, the heat sinks 266 may comprise a number of extending portions that provide a large surface area to be contacted by the material of the heat storage layer 262.

The composite thermal system 210 also includes a plurality of second heat sinks 268, each of the second heat sinks 268 adjacent to a respective of the plurality of the thermoelectric modules 232 on an opposing side from a respective of the first heat sinks 266, and providing a thermal path from its respective thermoelectric module 232 in a direction opposite from the heat storage layer 262. Thus, each of the second heat sinks acts to conduct heat between a respective thermoelectric module 232 along a path on the opposite side of the thermal conduction path to the heat storage layer 262.

The second supporting structure 276 may be attached to the first supporting structure 274 such that there is an air space 282 between these two structures. Heat conducted by each of the second heat sinks 268 is conducted from a respective thermoelectric module 232 and dissipated at the air space 282. The second heat sinks 268 should also be of a shape such that heat is dissipated between the first heat sinks 266 and the air space 282. For example, the heat sinks may comprise a number of extending portions that provide a large surface area to be contacted by the air in the air space 282. Air exchange between the air space 282 and air outside of the thermal system 210 may occur through natural ventilation, such as through vents in the second supporting structure 276, or via forced air.

The photovoltaic system 220 together with its supporting structure 276 may also act as a rain screen for the building, protecting the structural load bearing panel 280 from the weather. No other material or structure is therefore needed to weatherproof the building.

In operation as part of a building thermal envelope, the thermal system 210 receives and converts light energy during the day to thermal energy, and stores the thermal energy in the heat storage layer 262. During the night, presuming the night time external temperature is below the ambient internal building temperature desired, there is a temperature gradient between the outside air and the heat storage layer 262. In this case, the heat storage layer 262 slowly dissipates the heat stored towards the inside air. In addition, the heat storage layer will also dissipate stored heat outwards through the thermoelectric system towards the external air. In one embodiment this dissipating heat may be used to generate electricity by the thermoelectric system 230. The thus generated electrical energy may be stored, such as in a battery, or used immediately.

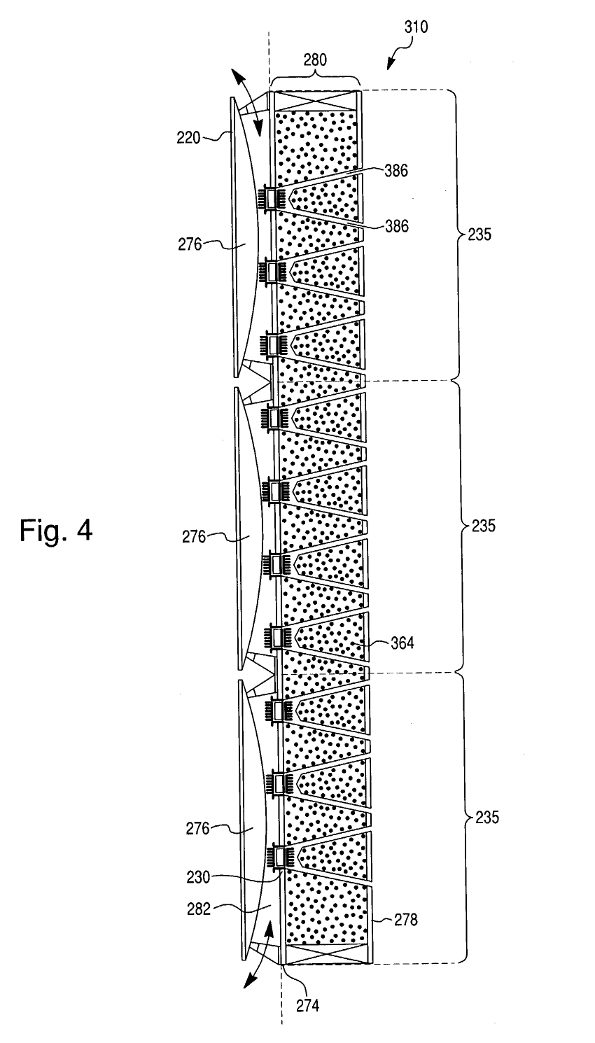

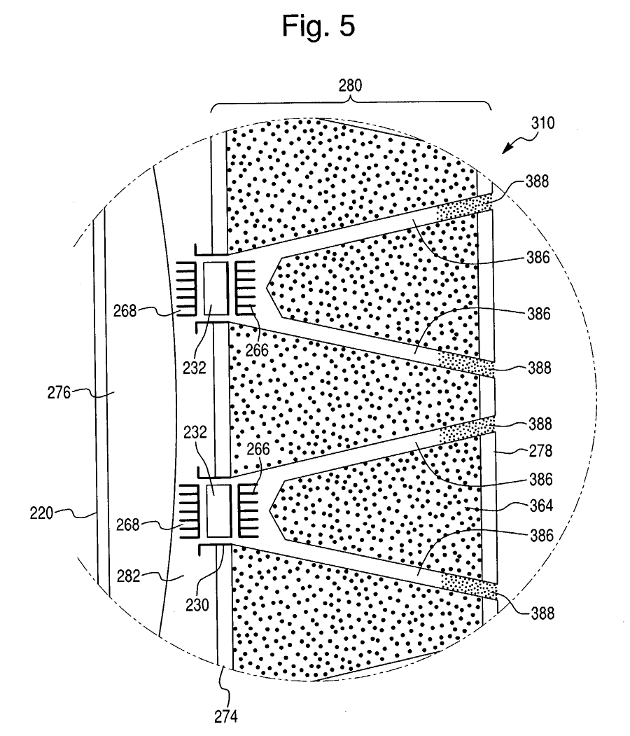

FIGS. 4 and 5 illustrate cross-sectional views of a composite thermal system 310 according to another embodiment of the present invention. FIG. 5 is an enlarged view of a portion of the composite thermal system illustrated in FIG. 4. In a similar fashion to the system of FIGS. 2 and 3, the composite thermal system 310 of FIGS. 4 and 5 may be an active building envelope system where the photovoltaic system 320 and the thermoelectric system 330 are part of a building thermal envelope. While the embodiment of FIGS. 2 and 3 may be most appropriate for use in a heating-dominated climate where heat storage in night time is important, the embodiment of FIGS. 4 and 5 may be most appropriate for use in a cooling-dominated climate where heat storage in night time is not as important.

In the embodiment of FIGS. 4 and 5, the composite thermal system 310 also includes a thermal insulating layer 364 in a similar fashion to the thermal insulating layer 264 of the embodiment of FIGS. 2 and 3. The embodiment of FIGS. 4 and 5, however, does not include the heat absorbing layer of the embodiment of FIGS. 2 and 3. The embodiment of FIGS. 4 and 5 also includes in a similar fashion to the embodiment of FIGS. 2 and 3, thermoelectric regions 235, first heat sinks 266, second heat sinks 268, a first supporting structure 274, a second supporting structure 276, a third supporting structure 278, load bearing panel 280, and other components denoted by the same numerals as in FIGS. 2 and 3.

As noted above, the composite thermal system 310 of FIGS. 4 and 5 may be particularly suited for a building thermal envelope in a cooling dominated climate. In this regard the composite thermal system 310 includes a number of ventilation pathways 386. Each of the ventilation pathways 386 extends from a corresponding thermoelectric module 232 through the thermal insulating layer 364. Heat generated by the thermoelectric modules 232 is convected through the ventilation pathways 386 from the thermoelectric modules 232, or vice versa if the modules 232 are in cooling mode. Air flow in the ventilation pathways 386 can be accomplished by means of natural ventilation or forced air ventilation, for example.

The composite thermal system 310 also includes a plurality of filters 388, each filter 388 disposed in a respective ventilation pathway 386. The filters act to inhibit dirt or bugs from entering the ventilation pathways 386. The filter 388 may be open pore filters, for example.

The thermal system 310 may also include first heat sinks 266, each of the first heat sinks 266 adjacent to a respective of the plurality of the thermoelectric modules 232 and providing a thermal path between its respective thermoelectric module 232 and a respective of the ventilation pathways 386. In this regard, it is preferred that the first heat sinks 266 have good thermal conduction properties, and may be made of a material with good heat conduction properties such as a metal, such as copper or aluminum., for example. The heat sinks should be in good thermal contact with the thermoelectric modules, for example by applying an adhesive with good thermal conductivity. The first heat sinks 266 should also be of a shape such that heat is dissipated between the first heat sinks 266 and the ventilation pathways 386. For example, the heat sinks may comprise a number of extending portions that provide a large surface area to be contacted by the air in the ventilation pathways 386.

When the thermoelectric modules 232 are operated to provide cooling, heat is dissipated from the air in the ventilation pathways to first heat sinks 266, and when operated to provide heating, heat flows in the opposite direction.

The composite thermal system 310 also includes a plurality of second heat sinks 268, each of the second heat sinks 268 adjacent to a respective of the plurality of the thermoelectric modules 232 on an opposing side from a respective of the first heat sinks 266, and providing a thermal path from its respective thermoelectric module 232 in a direction opposite from the thermal insulation layer 364. Thus, each of the second heat sinks 268 acts to conduct heat between a respective thermoelectric module 232 along a path on the opposite side of the thermal conduction path to the thermal insulation layer 364.

In a similar fashion to the embodiment of FIGS. 2 and 3, in the embodiment of FIGS. 3 and 4, heat conducted by each of the second heat sinks 268 is conducted from a respective thermoelectric module 232 and dissipated towards the air space 282. The second heat sinks 268 should also be of a shape such that heat is dissipated between the second heat sinks 268 and the air space 282. For example, the heat sinks 268 may comprise a number of extending portions that provide a large surface area to be contacted by the air in the air space 282. Air exchange between the air space 282 and air outside of the thermal system 310 may occur though natural ventilation, such as vents in the second supporting structure 276, or via forced air.

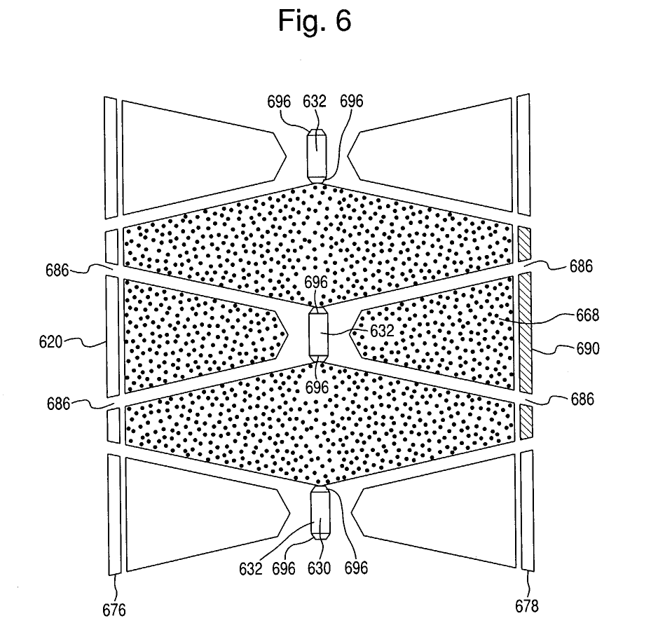

FIG. 6 is a cross-sectional view of another embodiment of a composite thermal system similar to the embodiment of FIGS. 4 and 5 in that both systems include ventilation pathways. The ventilation pathways in this embodiment, however, extend in directions on both sides of the thermoelectric modules.

The composite thermal system of FIG. 6 includes a front structural support 676 and a rear structural support 678, with a thermal insulation layer 668 between the front 676 and rear 678 structural supports. A thermoelectric system 630 comprising a plurality of thermoelectric modules 632 is embedded within the thermal insulation layer 668. A photovoltaic system 620 is disposed at the front of the thermoelectric system in line with or on the front structural support 676. A power distribution layer 690 may be located near the rear structural support 678 to distribute the electrical energy received from the photovoltaic system 620 to the thermoelectric modules 632 as needed.

Each of a plurality of ventilation pathways 686 extend from the front of the system to respective of the thermoelectric modules 632 and then to the back of the system. In operation, the air in the ventilation pathways 686 is either cooled or heated by the thermoelectric modules (depending on whether they are operated to provide heating or cooling).

Each of a plurality of valves 696 allows the air to pass directly past the thermoelectric modules 632 when opened. The valves 696 may be controlled to be opened when desired to allow flow of air past the thermoelectric modules 632. This mode of operation allows for direct ventilation through the composite wall system.

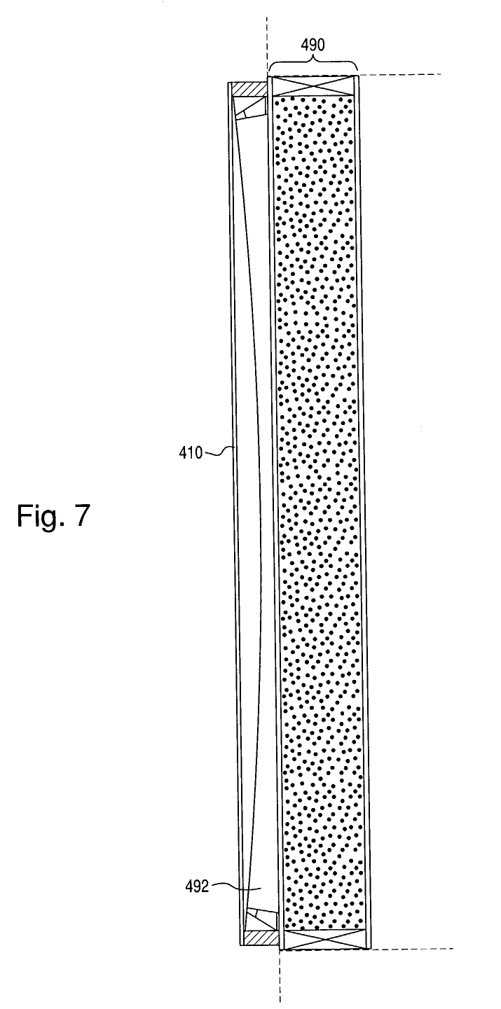

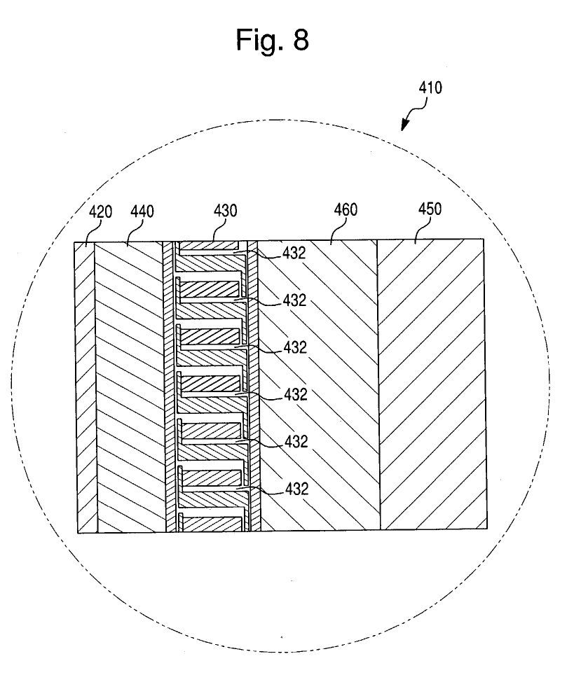

FIGS. 7 and 8 are cross-sectional views of a composite thermal system 410 according to an embodiment of the present invention. The composite thermal system 410 of this embodiment may be adapted to both heating-dominated and cooling-dominated climates. FIG. 8 is an enlarged view of a portion of the composite thermal system illustrated in FIG. 7. The composite thermal system 410 of FIGS. 7 and 8 includes a thermoelectric system, which in this embodiment is a thermoelectric layer 430, and a photovoltaic system, which in this embodiment is a photovoltaic layer 420, integral to the thermoelectric layer 430.

Preferably the thermoelectric layer 430 comprises thermoelectric modules 432 that are not spaced apart, but have an almost 100% density over the surface of the thermoelectric layer 430. Thus, the thermoelectric modules 432 cover substantially all of the surface of the thermoelectric layer 430. The thermoelectric layer 430 may comprise one or more thermoelectric devices, such as thermoelectric modules for example. The present invention is not limited to any particular type of thermoelectric device or material. In applications where the thermoelectric system 410 constitutes a building envelope, the thermoelectric layer 430 covers the entire building envelope running parallel to the photovoltaic layer 420.

The composite thermal system may also include a heat dissipation layer 440 disposed over the thermoelectric layer 430. The photovoltaic layer 420 is disposed over the heat dissipation layer 440. The heat dissipation layer can be composed of a metallic material with open cell structure, for example. Heat from the thermoelectric layer 430 flows to the heat dissipation layer 440 when the thermoelectric layer 430 is warmer than the heat dissipation layer 440, and is dissipated thereat. Conversely, when the thermoelectric layer 430 is cooler than the heat dissipation layer 440, heat from the heat dissipation layer 440 flows to the thermoelectric layer 430.

The composite thermal system 410 may optionally include a heat storage layer 460 disposed adjacent the thermoelectric layer 430. Heat from the thermoelectric layer flows to the heat storage layer 460 (and vice versa if the thermoelectric layer is in a cooling mode). The heat storage layer can be a phase change material, where the heat is stored as the latent heat of phase transformation of the phase change layer.

The composite thermal system 410 also may include a structural support layer 450 supporting the heat dissipation layer 440, thermoelectric layer 430, photovoltaic layer 420, and heat storage layer 460, if present. The structural support layer 450 may be made from a metallic or fiber reinforced polymeric composite material, for example. Alternatively, the heat storage layer 460 can also serve as a structural support layer. In the latter case, no separate support layer 450 is needed.

In this embodiment the total thickness of the photovoltaic layer 420, thermoelectric layer 430, heat dissipation layer 440, structural support layer 450 and heat storage layer 460, if included, may be less than 100 mm, for example. Thus, this embodiment provides the possibility of allowing for a thin thermal system, which can be readily incorporated into building envelope applications for new or existing building envelopes. In this regard, the thermal system 410 could be mounted to the outside of an existing building envelope 490 of an existing building. The system 410 may be mounted on the existing building envelope 490 as shown in FIG. 7 so as to provide a closed air space 492 between the system 410 and the existing building envelope 490. A closed air space 492 is formed in between the building envelope and the composite system 410. This air space 492 may be well insulated at the edges so that no external air is allowed to enter the space. In this case, the system 410 is used to thermally control the airspace in between the system 410 and the existing building envelope 490. Indirectly, this system 410 acts to thermally control the building.

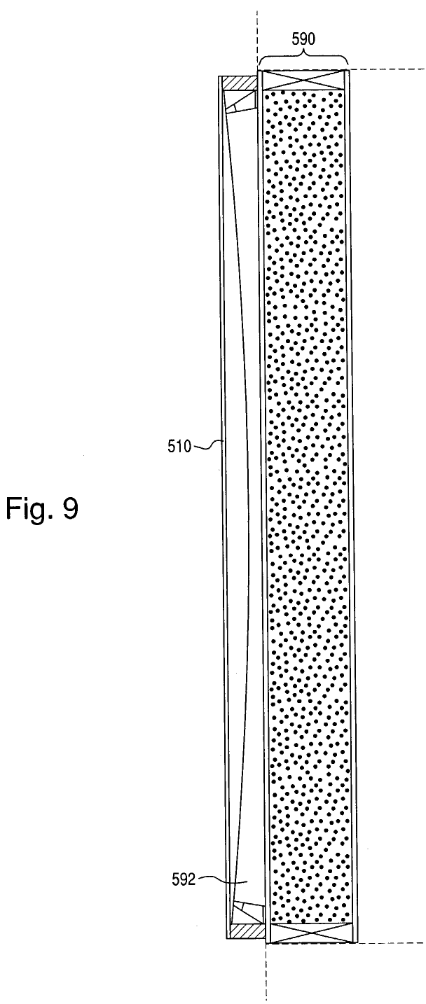

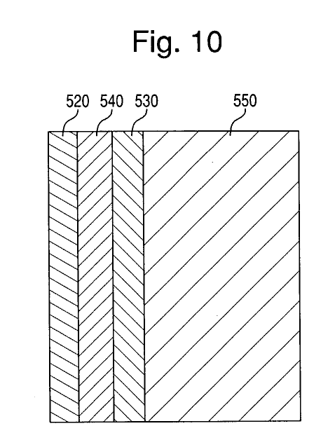

FIGS. 9 and 10 are cross-sectional views of a composite thermal system 510 according to an embodiment of the present invention. FIG. 10 is an enlarged view of a portion of the composite thermal system 510 illustrated in FIG. 9. The composite thermal system 510 of this embodiment may be adapted to both heating-dominated and cooling-dominated climates. The composite thermal system 510 is similar to that of FIGS. 7 and 8 in that the overall thickness of the system can be made relatively thin. In the embodiment of FIGS. 9 and 10, because thin film thermoelectric systems and thin film photovoltaic systems are employed, the overall thickness can be even lower than that of the embodiment of FIGS. 7 and 8.

Returning to FIGS. 9 and 10, in the composite thermal system 510 the thermoelectric system comprises a thin film thermoelectric layer 530, and the photovoltaic system comprises a thin film photovoltaic layer 520. In a similar fashion to the embodiment of FIGS. 7 and 8, the total thickness of the thermal system in the Embodiment of FIGS. 9 and 10 may be quite thin. In fact, because thin film materials are used, the total thickness may be even less, 500 micrometers or less for total thickness of the layers other than the structural support layer 550, or even 100 micrometers or less.

The composite thermal system 510 may include a thin film heat dissipation layer 540 disposed over the thermoelectric thin film layer 530. The photovoltaic thin film layer 520 is disposed over the thin film heat dissipation layer 540. A thin film metallic material can be used as the heat dissipation layer, for example. Heat from the thermoelectric thin film layer 530 flows to the heat dissipation thin film layer 540 when the thermoelectric thin film layer 530 is warmer than the heat dissipation thin film layer 540, and is dissipated thereat. Conversely, when the thermoelectric thin film layer 530 is cooler than the heat dissipation thin film layer 540, heat from the heat dissipation thin film layer 540 flows to the thermoelectric thin film layer 530.

The composite thermal system 510 may also include a structural support layer 550 supporting the heat dissipation thin film layer 540, thermoelectric thin film layer 530, and photovoltaic thin film layer 520. The structural support layer may be a metallic, polymeric, or ceramic material, for example.

In this embodiment the total thickness of the photovoltaic thin film layer 520, thermoelectric thin film layer 530, and heat dissipation thin film layer 540, may be less than 500 micrometers, or even less than 100 micrometers, for example. Thus, this embodiment provides the possibility of allowing for a very thin thermal system, which can be readily incorporated into a number of applications. In addition, since thin film thermoelectric and thin film photovoltaic materials are used in this embodiment, this embodiment can be made transparent or translucent. For example, for building envelope applications, the structural support layer 550 could be made of a transparent glass or other transparent material, and the composite thermal system 510 can be used as a glazing system for buildings. Alternatively, when attached to an opaque structural support layer, the composite thermal system 510 can be attached to the outside of an existing building envelope 590 of an existing building in a similar fashion to the embodiments of FIGS. 7 and 8. In this regard, the system 510 may be mounted on the existing building envelope 590 as shown in FIG. 9 so as to provide a closed air space 592 between the system 510 and the existing building envelope 590. A closed air space 592 is formed in between the building envelope and the composite system 510.

In addition to building applications, the composite thermal system 510 could be employed in packaging applications, for example. For example, the composite thin film thermal system 510 could be applied to the surface of a bottle of refreshment or other storage container, or to the surface of other objects that are intended to be kept cool. The composite thermal system 510 could then actively cool the object when the object is in the sunlight. Other applications include the use of transparent thin film thermal composite systems 510 for automobile windows. The internal automobile space could then actively be cooled when exposed to sunlight. Alternatively, the thin film composite thermal system of embodiment 510 can also be used to heat objects or surfaces above ambient temperatures.

In addition to building and packaging applications, the composite thermal system could also be employed in aerospace applications, for example. For example, the composite thermal system could be applied to construct the external skin of a space station or space transport vessel. In this application, solar energy is directly used to thermally condition the internal space of the space station or space transport vessel. In addition, the composite thermal system in this application actively counteracts thermal structural stresses that are encountered in these structures when the structures are unevenly exposed to solar radiation. The thermal control capabilities of the composite thermal system may also be used to thermally condition the fuselage or wing structures of airplanes, for example.

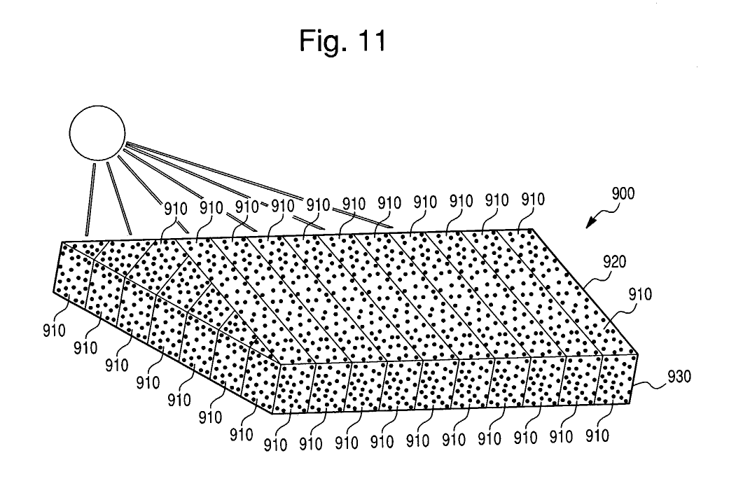

FIG. 11 illustrates composite thermal system panels 910 as part of a building 900. The composite thermal system panels 910 may comprise the composite thermal system of any one of the earlier embodiments of FIGS. 1-9. The composite thermal system panels 910 may comprise part of a roof 920 and/or walls 930 of the building 900. Some or all of the overall building thermal envelope may comprise the panels 910. For example, the panels 910 may be disposed only in the roof 920, only in the walls 930, or as a portion of the walls 930 or roof 920.

Preferably the panels 910 are disposed at least as part of the walls 930 and roof 920 that face in different directions. Thus, the electrical power generated at panels receiving sunlight may be redistributed to those panels which are in shade or in little sunlight. This allows the photovoltaic system (not shown in FIG. 11) of the panels 910 to receive sunlight generated power during most of the day time, even if only some of the panels 910 are in sunlight during part of the day time. The panel 910 may remain stationary as opposed to tracked panels that are moved to track the movement of the sun. Although such stationary panels may have a lower efficiency than the tracked panels, the efficiency may be sufficient in many applications because the panels 910 are incorporated throughout the building 900.

While the above embodiments illustrate the layers of the composite thermal system in a particular order, the invention is not so limited. The layers may be arranged in an order other than that illustrated in the drawings. For example, in the embodiment of FIGS. 9 and 10, the thermoelectric thin film layer 530 may be disposed between the heat dissipation thin film layer 540 and the photovoltaic thin film layer 520.

While the invention has been described in detail and with reference to specific embodiments thereof, it will be apparent to one skilled in the art that various changes and modifications can be made therein without departing from the spirit and scope of the invention. Thus, the breadth and scope of the present invention should not be limited by any of the above-described exemplary embodiments, but should be defined only in accordance with the following claims and their equivalents.

What is claimed is:

1. A composite thermal system comprising:
a thermoelectric system that converts electrical energy into thermal energy; and
a photovoltaic system that converts light energy into electrical energy, wherein the photovoltaic system is integral with and electrically connected to the thermoelectric system for providing electrical energy to the thermoelectric system.

2. The composite thermal system of claim 1, further comprising:
a substrate; and
wherein the thermoelectric system comprises a thin film thermoelectric layer formed over the substrate, and the photovoltaic system comprises a thin film photovoltaic layer formed over the substrate.

3. The composite thermal system of claim 2, wherein the thin film photovoltaic layer is formed over the thin film thermoelectric layer.

4. The composite thermal system of claim 2, wherein the substrate is transparent.

5. The composite thermal system of claim 2, wherein the substrate comprises a glazing.

6. The composite thermal system of claim 2, wherein the substrate comprises glass.

7. The composite thermal system of claim 2, wherein the composite thermal system is arranged on the surface of a storage container.

8. The composite thermal system of claim 2, wherein the composite thermal system is arranged on the window of an automobile.

9. The composite thermal system of claim 2, wherein the composite thermal system is arranged as part of the skin of a space station or a space transport vessel.

10. The composite thermal system of claim 2, further comprising:
a heat storage layer disposed between the thin film thermoelectric layer and the substrate.

11. The composite thermal system of claim 2, wherein the total thickness of the thin film thermoelectric layer and the thin film photovoltaic layer is less than 500 micrometers.

12. The composite thermal system of claim 1, wherein the thermoelectric system comprises a plurality of thermoelectric modules.

13. The composite thermal system of claim 12, further comprising:
a heat storage layer, wherein the thermoelectric modules are disposed adjacent to and thermally connected to the heat storage layer.

14. The composite thermal system of claim 13, further comprising:
a thermal insulation layer comprising a plurality of thermal insulation regions, the thermal insulation regions are disposed adjacent to the heat storage layer and laterally adjacent the plurality of thermoelectric modules.

15. The composite thermal system of claim 13, further comprising:
a plurality of first heat sinks, each of the first heat sinks is adjacent to a respective of the plurality of the thermoelectric modules and providing a thermal path between its respective thermoelectric module and the heat storage layer.

16. The composite thermal system of claim 13, further comprising:
a plurality of second heat sinks, each of the second heat sinks is adjacent to a respective one of the plurality of the thermoelectric modules on an opposing side from a respective of the first heat sinks, and providing a thermal path from its respective thermoelectric module in a direction opposite from the heat storage layer.

17. The composite thermal system of claim 16, wherein the photovoltaic system is disposed to provide an air space between the photovoltaic system and the second heat sinks, and wherein each of the second heat sinks provides a thermal path from its respective thermoelectric module to the air space.

18. The composite thermal system of claim 13, further comprising:
a first support structure supporting the plurality of thermoelectric modules and heat storage layer; and
a second support structure supporting a photovoltaic layer of the photovoltaic system, and wherein the second support structure is supported by the first support structure.

19. The composite thermal system of claim 18, wherein an air space is disposed between the first and second support structures.

20. The composite thermal system of claim 18, further comprising:
a thermal insulation layer comprising a plurality of thermal insulation regions, the thermal insulation regions are disposed between the heat storage layer and the first support structure and laterally adjacent the plurality of thermoelectric modules.

21. The composite thermal system of claim 12, wherein the photovoltaic system is disposed on a first side of the plurality of thermoelectric modules, and the composite thermal system further comprising:
a thermal insulation layer disposed on a second side of the plurality of thermoelectric modules opposite to the first side, the thermal insulation layer having a plurality of ventilation pathways, each ventilation pathway extending from a respective thermoelectric module of the plurality of thermoelectric modules into the thermal insulation layer.

22. The composite thermal system of claim 21, further comprising a plurality of air filters, each air filter disposed in a respective ventilation pathway of the plurality of ventilation pathways.

23. The composite thermal system of claim 21, further comprising:
a plurality of first heat sinks, each of the first heat sinks is adjacent to a respective of the plurality of the thermoelectric modules and providing a thermal path between its respective thermoelectric module and a respective of the ventilation pathways.

24. The composite thermal system of claim 23, further comprising:
a plurality of second heat sinks, each of the second heat sinks is adjacent to a respective of the plurality of the thermoelectric modules on an opposing side from a respective of the first heat sinks, and providing a thermal path from its respective thermoelectric module in a direction opposite from the thermal insulation layer.

25. The composite thermal system of claim 24, wherein the photovoltaic system is disposed to provide an air space between the photovoltaic system and second heat sinks, and wherein each of the second heat sinks provides a thermal path from its respective thermoelectric module to the air space.

26. The composite thermal system of claim 21, further comprising:
a first support structure supporting the plurality of thermoelectric modules and thermal insulation layer; and
a second support structure supporting a photovoltaic layer of the photovoltaic system, and wherein the second support structure is supported by the first support structure.

27. The composite thermal system of claim 26, wherein an air space is disposed between the first and second support structures.

28. The composite thermal system of claim 1, wherein the thermoelectric system comprises a thermoelectric layer and the photovoltaic system comprises a photovoltaic layer.

29. The composite thermal system of claim 28, further comprising:
a heat dissipation layer disposed over the thermoelectric layer, wherein the photovoltaic layer is disposed over the heat dissipation layer.

30. The composite thermal system of claim 28, wherein the heat dissipation layer comprises a cellular metallic substrate or an adhesive with good thermal conductivity.

31. The composite thermal system of claim 28, further comprising:
a structural support layer, wherein the thermoelectric layer is formed over the structural support layer.

32. The composite thermal system of claim 31, wherein the total thickness of the thermoelectric layer, the photovoltaic layer, and the structural support layer is less than 100 mm.

33. The composite thermal system of claim 31, further comprising:
a heat storage layer disposed between the thermoelectric layer and the structural support layer.

34. The composite thermal system of claim 33, wherein the heat storage layer comprises a phase change material.

35. The composite thermal system of claim 1, further comprising:
an electrical distribution system that distributes electrical energy provided from the photovoltaic system to the thermoelectric system.

36. The composite thermal system of claim 35, further comprising:
an electrical storage system that stores some of the electrical energy provided from the photovoltaic system.

37. The composite thermal system of claim 35, wherein the thermoelectric system comprises a plurality of thermoelectric regions, and further comprising:
a plurality of temperature sensors, each temperature sensor detecting a temperature of a respective of the thermoelectric regions; and
a thermal control system controlling the electrical distribution system to distribute electrical energy provide from the photovoltaic system based on signals from the temperature sensors.

38. The composite thermal system of claim 1, wherein the system is arranged as at least a portion of a building thermal envelope.

39. A method of controlling the temperature of a structure, the structure comprising a thermoelectric system that converts electrical energy into thermal energy, a photovoltaic system that converts light energy into electrical energy, wherein the photovoltaic system is integral with and electrically connected to the thermoelectric system for providing electrical energy to the thermoelectric system, and a plurality of thermoelectric regions, the method comprising:
controlling the electrical energy provided by the photovoltaic system to the thermoelectric system so that at least some of the thermoelectric regions have different temperatures.

40. The method of claim 39, wherein the structure comprises a building, and the thermoelectric regions respectively correspond to rooms of the building.

41. A method of controlling the temperature of a building, the building comprising a thermal envelope comprising a thermoelectric system that converts electrical energy into thermal energy, a photovoltaic system that converts light energy into electrical energy, wherein the photovoltaic system is integral with and electrically connected to the thermoelectric system for providing electrical energy to the thermoelectric system, the method comprising:
converting light energy to electrical energy via the photovoltaic system during the day and transferring the electrical energy to thermoelectric system;
converting the transferred electrical energy via the thermoelectric system to thermal energy to heat a heat storage layer of the thermal envelope;
dissipating heat from the heat storage layer to the thermoelectric system towards air external to the building during the night; and
using the dissipating heat to generate electricity via the thermoelectric system.

42. The composite thermal system of claim 11, wherein the total thickness of the thin film thermoelectric layer and the thin film photovoltaic layer is less than 100 micrometers.

43. The composite thermal system of claim 1, wherein the composite thermal system is arranged as part of the skin of a space station or a space transport vessel.

44. The composite thermal system of claim 1, further comprising:
a heat storage layer disposed between the thin film thermoelectric layer and the substrate.
